(19) United States
(12) Patent Application Publication
(10) Pub. No.: US 2025/0113698 A1
(43) Pub. Date: Apr. 3, 2025

(54) ENGINEERED SCATTERING IN LED ENCAPSULANTS FOR TUNABLE OPTICAL FAR-FIELD RESPONSE

(71) Applicant: Lumileds LLC, San Jose, CA (US)

(72) Inventors: Matthew ROZIN, Santa Clara, CA (US); Noad Shapiro, Fremont, CA (US)

(73) Assignee: Lumileds LLC, San Jose, CA (US)

(21) Appl. No.: 18/963,147

(22) Filed: Nov. 27, 2024

Related U.S. Application Data
(63) Continuation of application No. PCT/US2023/025819, filed on Jun. 21, 2023.
(60) Provisional application No. 63/355,483, filed on Jun. 24, 2022.

(51) Int. Cl. H10H 29/80; H10H 29/14; H10H 29/851

(52) U.S. Cl. CPC H10H 29/882; H10H 29/142; H10H 29/8513

(57) ABSTRACT

A light engine with distinct light sources sharing at least one optic may employ scattering particles to change the illuminance line profiles of one or more of the light sources so that they are more uniformly mixed in the far-field. The scattering particles may be integrated into phosphor layers of specific light sources or may be disposed in a separate layer. The scattering particles may be tunable based on the particular characteristics of the light source, such as their spectral characteristics or their chemical mixing characteristics.

### CROSS REFERENCE TO RELATED APPLICATIONS

This application is a continuation of PCT Application PCT/US2023/025819 filed Jun. 21, 2023, which claims benefit of priority to U.S. provisional application No. 63/355,483 filed on Jun. 24, 2022. Both of the above applications are incorporated by reference in this application in their entirety.

### STATEMENT REGARDING FEDERALLY SPONSORED RESEARCH OR DEVELOPMENT

This invention was made with government support under DE-EE0009167 awarded by The U.S. Department of Energy. The government has certain rights in the invention.

### FIELD OF THE INVENTION

The disclosure relates generally to LEDs, pcLEDs, LED and pcLED arrays, light sources comprising LEDs, pcLEDs, LED arrays, or pcLED arrays, and displays comprising LED or pcLED arrays. Particularly, this disclosure relates to methods and devices of integrating a phosphor to an semiconductor light emitting diode.

### BACKGROUND

Semiconductor light emitting diodes and laser diodes (collectively referred to herein as “LEDs”) are among the most efficient light sources currently available. The emission spectrum of an LED typically exhibits a single narrow peak at a wavelength determined by the structure of the device and by the composition of the semiconductor materials from which it is constructed. By suitable choice of device structure and material system, LEDs may be designed to operate at ultraviolet, visible, or infrared wavelengths.

LEDs may be combined with one or more wavelength converting materials (generally referred to herein as “phosphors”) that absorb light emitted by the LED and in response emit light of a longer wavelength. For such phosphor-converted LEDs (“pcLEDs”), the fraction of the light emitted by the LED that is absorbed by the phosphors depends on the amount of phosphor material in the optical path of the light emitted by the LED, for example on the concentration of phosphor material in a phosphor layer disposed on or around the LED and the thickness of the layer. Phosphor-converted LEDs may be designed so that all the light emitted by the LED is absorbed by one or more phosphors, in which case the emission from the pcLED is entirely from the phosphors. In such cases the phosphor may be selected, for example, to emit light in a narrow spectral region that is not efficiently generated directly by an LED. Alternatively, pcLEDs may be designed so that only a portion of the light emitted by the LED is absorbed by the phosphors, in which case the emission from the pcLED is a mixture of light emitted by the LED and light emitted by the phosphors. By suitable choice of LED, phosphors, and phosphor composition, such a pcLED may be designed to emit, for example, white light having a desired color temperature and desired color-rendering properties.

Technological and business applications of LEDs and pcLEDs include use in displays, matrices and light engines including automotive adaptive headlights, augmented-reality (AR) displays, virtual-reality (VR) displays, mixed-reality (MR) displays, smart glasses and displays for mobile phones, smart watches, monitors and TVs, and flash illumination for cameras in mobile phones. For example, backlights for liquid crystal-displays typically employ pcLEDs comprising a combination of green and red phosphors. The individual LEDs or pcLEDs in these architectures can have an area of a few square millimeters down to a few square micrometers (microLEDs).

LEDs and pcLEDs are used in luminaires or light engines, which provide illumination for general purposes such as to light up a room. Light engines often combine spectrally distinct sources to be blended together into a uniform beam in order to provide light of the proper color and intensity. A primary optic may be used in these light engines to blend these light sources in the far-field. However, in order to obtain properly uniform mixing, these light engines may also need to utilize further secondary optics in addition to the primary optic, in order to accommodate different scattering profiles of various sources within the light engine. This may be necessary whether the light engine utilizes segmented LEDs of different colors, or phosphor converted versus direct-emitting LEDs. These secondary optics are bulky and adding them to the light engines is undesirable. What is needed is a more elegant solution which both allows blending of different light sources into a uniform beam in the far-field.

### SUMMARY

Embodiments of this invention include methods and devices of combining different sources of light to enable uniform mixing of the different sources in the far-field. Particularly, a light engine with spectrally distinct sources sharing at least one optic may employ scattering particles to broaden or narrow the luminance line profiles of one or more of the light sources so that the light sources are uniformly spatially mixed in the far-field. The scattering particles may be integrated into phosphor layers of specific light sources or may be disposed in a separate layer. The scattering particles may be disposed over some or all of the light sources, and may be tunable based on the particular characteristics of the light source, spectral or otherwise.

Additional aspects and advantages of the present disclosure will become readily apparent to those skilled in this art from the following detailed description, wherein only illustrative embodiments of the present disclosure are shown and described. As will be realized, the present disclosure is capable of other and different embodiments, and its several details are capable of modifications in various obvious respects, all without departing from the disclosure.

Accordingly, the drawings and description are to be regarded as illustrative in nature, and not as restrictive.

### BRIEF DESCRIPTION OF THE DRAWINGS

FIG. 1 shows a schematic cross-sectional view of an example pcLED.

FIGS. 2A and 2B show, respectively, cross-sectional and top schematic views of an array of pcLEDs.

FIG. 3A shows a schematic top view of an electronics board on which an array of pcLEDs may be mounted, and FIG. 3B similarly shows an array of pcLEDs mounted on the electronic board of FIG. 3A.

FIG. 4A shows a schematic cross-sectional view of an array of pcLEDs arranged with respect to waveguides and a projection lens. FIG. 4B shows an arrangement similar to that of FIG. 4A, without the waveguides.

FIG. 5 schematically illustrates an example camera flash system.

FIG. 6 schematically illustrates an example display (e.g., AR/VR/MR) system.

FIG. 7 shows a cross-sectional view of a light emitting device a first light emitting array and a second light emitting array including scattering particles.

FIG. 8 shows a cross-sectional view of a light emitting device a first light emitting array including scattering particles and a second light emitting array including scattering particles.

FIG. 9 shows a cross-sectional view of a light emitting device a first light emitting array including scattering particles and a second light emitting array without a phosphor layer including a layer of scattering particles.

FIG. 10 shows a cross-sectional view of a light emitting device a first light emitting array with phosphor particles and a second light emitting array without a phosphor layer including a layer of scattering particles.

FIG. 11 shows a cross-sectional view of a light emitting device with three light emitting arrays, each with phosphor layers including scattering particles in the phosphor layers.

FIG. 12 shows a cross-sectional view of a light emitting device a first light emitting array with a layer of scattering particles separate from the layer of phosphor particles and a second light emitting array with a layer of scattering particles separate from the layer of phosphor particles.

FIG. 13 shows a cross-sectional view of a light emitting device a first light emitting array with a spatially varying layer of phosphor particles and a spatially varying layer of scattering particles.

FIG. 14 shows an actual visual of single pixels of three different colors being turned on, and their corresponding luminance line profiles.

FIG. 15 shows an actual visual of arrays of pixels of three different colors being turned on, and their corresponding luminance line profiles.

### DETAILED DESCRIPTION

The following detailed description should be read with reference to the drawings, in which identical reference numbers refer to like elements throughout the different figures. The drawings, which are not necessarily to scale, depict selective embodiments and are not intended to limit the scope of the invention. The detailed description illustrates by way of example, not by way of limitation, the principles of the invention.

FIG. 1 shows an example of an individual pcLED 100 comprising a light emitting semiconductor diode (LED) structure 102 disposed on a substrate 104, and a phosphor layer 106 (also referred to herein as a wavelength converting structure) disposed on the LED. Light emitting semiconductor diode structure 102 typically comprises an active region disposed between n-type and p-type layers. Application of a suitable forward bias across the diode structure results in emission of light from the active region. The wavelength of the emitted light is determined by the composition and structure of the active region.

The LED may be, for example, a III-Nitride LED that emits ultraviolet, blue, green, or red light. LEDs formed from any other suitable material system and that emit any other suitable wavelength of light may also be used. Other suitable material systems may include, for example, III-Phosphide materials, III-Arsenide materials, and II-VI materials.

Any suitable phosphor materials may be used, depending on the desired optical output and color specifications for the pcLED. Phosphor layers may for example comprise phosphor particles dispersed in or bound to each other with a binder material, or be or comprise a sintered ceramic phosphor plate.

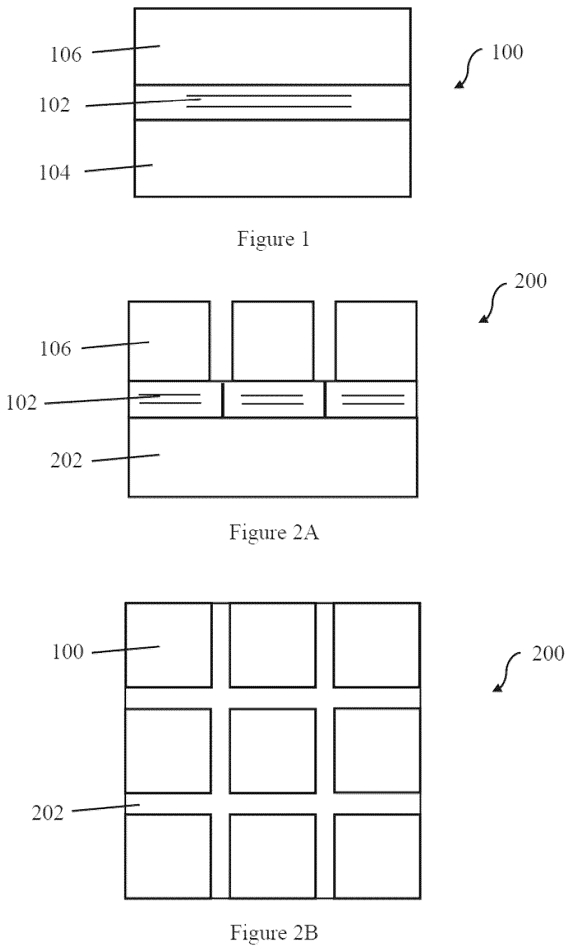

FIGS. 2A-2B show, respectively, cross-sectional and top views of an array 200 of pcLEDs 100 including phosphor layers 106 disposed on a substrate 202. Such an array may include any suitable number of pcLEDs arranged in any suitable manner. In the illustrated example the array is depicted as formed monolithically on a shared substrate, but alternatively an array of pcLEDs may be formed from individual mechanically separate pcLEDs arranged on a substrate. Substrate 202 may optionally comprise CMOS circuitry for driving the LED and may be formed from any suitable materials.

Although FIGS. 2A-2B show a three-by-three array of nine pcLEDs, such arrays may include for example tens, hundreds, or thousands of LEDs. Individual LEDs may have widths (e.g., side lengths) in the plane of the array of, for example, less than or equal to 1 millimeter (mm), less than or equal to 500 microns, less than or equal to 100 microns, or less than or equal to 50 microns. LEDs in such an array may be spaced apart from each other by streets or lanes having a width in the plane of the array of, for example, hundreds of microns, less than or equal to 100 microns, less than or equal to 50 microns, less than or equal to 10 microns, or less than or equal to 5 microns.

LEDs having dimensions in the plane of the array (e.g., side lengths) of less than or equal to about 50 microns are typically referred to as microLEDs, and an array of such microLEDs may be referred to as a microLED array.

Although the illustrated examples show rectangular LEDs or pcLEDs arranged in a symmetric matrix, the LEDs or pcLEDs and the array may have any suitable shape or arrangement and need not all be of the same shape or size. For example, LEDs or pcLEDs located in central portions of an array may be larger than those located in peripheral portions of the array. Alternatively, LEDs or pcLEDs located in central portions of an array may be smaller than those located in peripheral portions of the array.

In an array of pcLEDs, all pcLEDs may be configured to emit essentially the same spectrum of light. Alternatively, a pcLED array may be a multicolor array in which different pcLEDs in the array may be configured to emit different spectrums (colors) of light by employing different phosphor compositions. Similarly, in an array of direct emitting LEDs (i.e., not wavelength converted by phosphors) all LEDs in the array may be configured to emit essentially the same spectrum of light, or the array may be a multicolor array comprising LEDs configured to emit different colors of light.

The individual LEDs or pcLEDs in an array may be individually operable (addressable) and/or may be operable as part of a group or subset of (e.g., adjacent) LEDs or pcLEDs in the array.

An array of LEDs or pcLEDs, or portions of such an array, may be formed as a segmented monolithic structure in which individual LEDs or pcLEDs are electrically isolated from each other by trenches and/or insulating material, but the electrically isolated segments remain physically connected to each other by portions of the semiconductor structure.

An LED or pcLED array may therefore be or comprise a monolithic multicolor matrix of individually operable LED or pcLED light emitters. The LEDs or pcLEDs in the monolithic array may for example be microLEDs as described above.

A single individually operable LED or pcLED or a group of adjacent such LEDs or pcLEDs may correspond to a single pixel (picture element) in a display. For example, a group of three individually operable adjacent LEDs or pcLEDs comprising a red emitter, a blue emitter, and a green emitter may correspond to a single color-tunable pixel in a display.

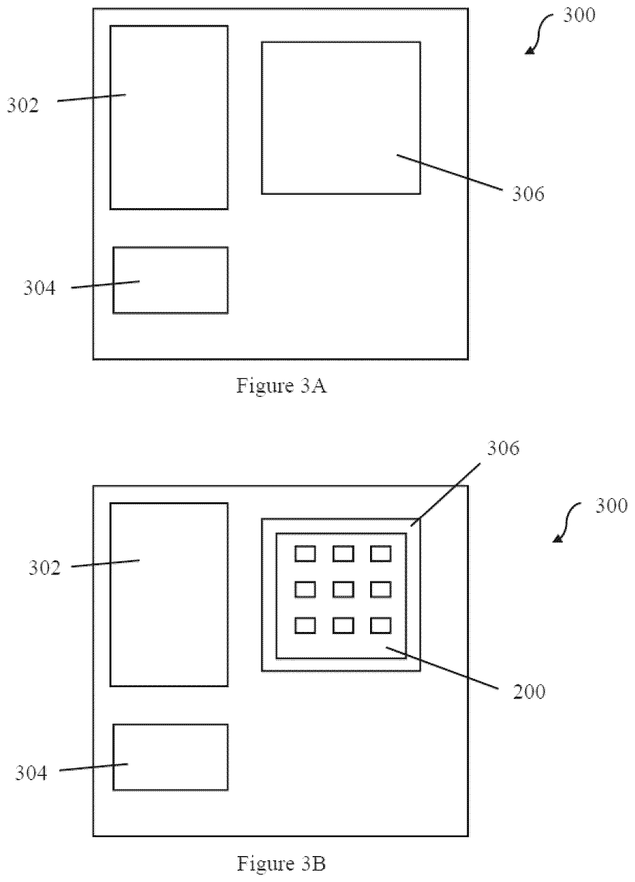

As shown in FIGS. 3A-3B, an LED or pcLED array 200 may be mounted on an electronics board 300 comprising a power and control module 302, a sensor module 304, and an attach region 306. Power and control module 302 may receive power and control signals from external sources and signals from sensor module 304, based on which power and control module 302 controls operation of the LEDs/pcLEDs. Sensor module 304 may receive signals from any suitable sensors, for example from temperature or light sensors. Alternatively, array 200 may be mounted on a separate board (not shown) from the power and control module and the sensor module.

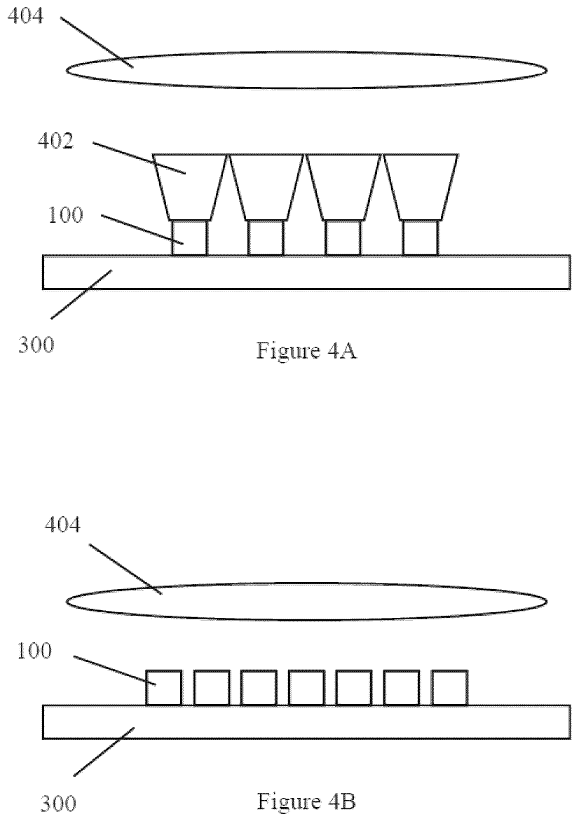

Individual LEDs or pcLEDs may optionally incorporate or be arranged in combination with a lens or other optical element located adjacent to or disposed on the phosphor layer. Such an optical element, not shown in the figures, may be referred to as a “primary optical element”. In addition, as shown in FIGS. 4A-4B an array 200 (for example, mounted on an electronics board 300) may be arranged in combination with secondary optical elements such as waveguides, lenses, or both for use in an intended application. In FIG. 4A, light emitted by pcLEDs 100 is collected by waveguides 402 and directed to projection lens 404. Projection lens 404 may be a Fresnel lens, for example. This arrangement may be suitable for use, for example, in automobile headlights. In FIG. 4B, light emitted by pcLEDs 100 is collected directly by projection lens 404 without use of intervening waveguides. This arrangement may be particularly suitable when LEDs or pcLEDs can be spaced sufficiently close to each other and may also be used in automobile headlights as well as in camera flash applications. A microLED display application may use similar optical arrangements to those depicted in FIGS. 4A-4B, for example.

In another example arrangement, a central block of LEDs or pcLEDs in an array may be associated with a single common (shared) optic, and edge LEDs or pcLEDs located in the array at the periphery of the central bloc are each associated with a corresponding individual optic.

Generally, any suitable arrangement of optical elements may be used in combination with the LED and pcLED arrays described herein, depending on the desired application.

LED and pcLED arrays as described herein may be useful for applications requiring or benefiting from fine-grained intensity, spatial, and temporal control of light distribution. These applications may include, but are not limited to, precise special patterning of emitted light from individual LEDs or pcLEDs or from groups (e.g., blocks) of LEDs or pcLEDs. Depending on the application, emitted light may be spectrally distinct, adaptive over time, and/or environmentally responsive. Such arrays may provide pre-programmed light distribution in various intensity, spatial, or temporal patterns. The emitted light may be based at least in part on received sensor data and may be used for optical wireless communications. Associated electronics and optics may be distinct at an individual LED/pcLED, group, or device level.

An array of independently operable LEDs or pcLEDs may be used in combination with a lens, lens system, or other optic or optical system (e.g., as described above) to provide illumination that is adaptable for a particular purpose. For example, in operation such an adaptive lighting system may provide illumination that varies by color and/or intensity across an illuminated scene or object and/or is aimed in a desired direction. Beam focus or steering of light emitted by the LED or pcLED array can be performed electronically by activating LEDs or pcLEDs in groups of varying size or in sequence, to permit dynamic adjustment of the beam shape and/or direction without moving optics or changing the focus of the lens in the lighting apparatus. A controller can be configured to receive data indicating locations and color characteristics of objects or persons in a scene and based on that information control LEDs or pcLEDs in an array to provide illumination adapted to the scene. Such data can be provided for example by an image sensor, or optical (e.g., laser scanning) or non-optical (e.g., millimeter radar) sensors. Such adaptive illumination is increasingly important for automotive (e.g, adaptive headlights), mobile device camera (e.g., adaptive flash), VR, and AR applications such as those described below.

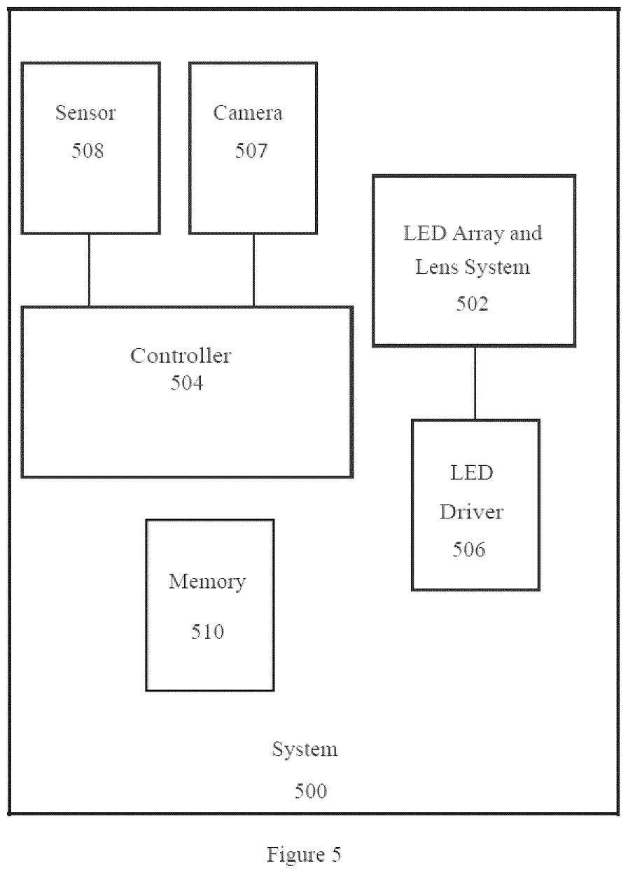

FIG. 5 schematically illustrates an example camera flash system 500 comprising an LED or pcLED array and lens system 502, which may be or comprise an adaptive lighting system as described above in which LEDs or pcLEDs in the array may be individually operable. In operation of the camera flash system, illumination from some or all of the LEDs or pcLEDs in array and lens system 502 may be adjusted-deactivated, operated at full intensity, or operated at an intermediate intensity. The array may be a monolithic array, or comprise one or more monolithic arrays, as described above. The array may be a microLED array, as described above.

Flash system 500 also comprises an LED driver 506 that is controlled by a controller 504, such as a microprocessor. Controller 504 may also be coupled to a camera 507 and to sensors 508 and operate in accordance with instructions and profiles stored in memory 510. Camera 507 and LED or pcLED array and lens system 502 may be controlled by controller 504 to, for example, match the illumination provided by system 502 (i.e., the field of view of the illumination system) to the field of view of camera 507, or to otherwise adapt the illumination provided by system 502 to the scene viewed by the camera as described above. Sensors 508 may include, for example, positional sensors (e.g., a gyroscope and/or accelerometer) and/or other sensors that may be used to determine the position and orientation of system 500.

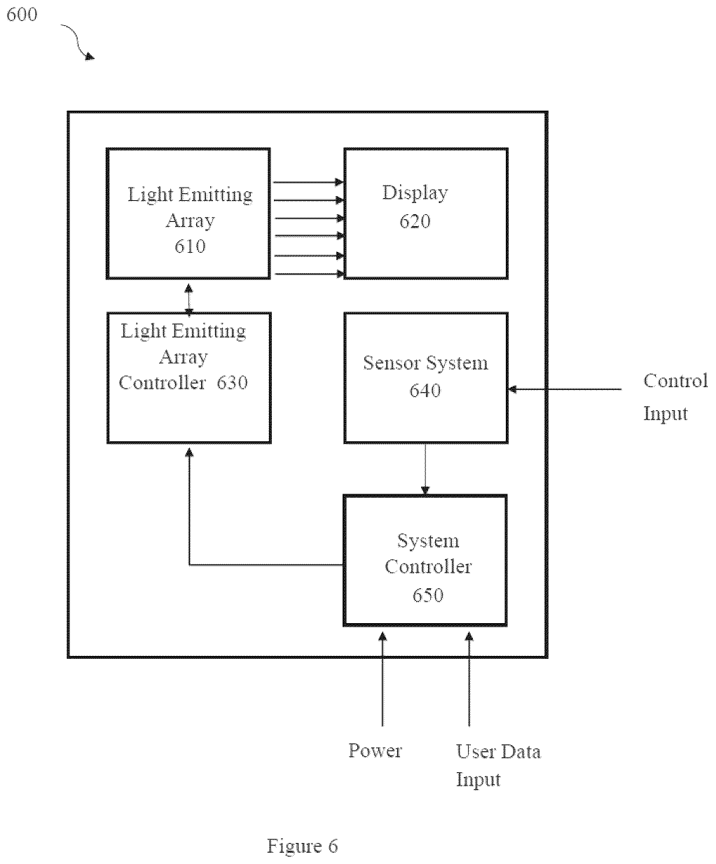

FIG. 6 schematically illustrates an example display (e.g., AR/VR/MR) system 600 that includes an array 610 of individually operable LEDs or pcLEDs, a display 620, a light emitting array controller 630, a sensor system 640, and a system controller 650. Array 610 may be a monolithic array, or comprise one or more monolithic arrays, as described above. The array may be monochromatic. Alternatively, the array may be a multicolor array in which different LEDs or pcLEDs in the array are configured to emit different colors of light, as described above. The array may therefore be or comprise a monolithic multicolor matrix of individually operable LED or pcLED light emitters, which may for example be microLEDs as described above. A single individually operable LED or pcLED or a group of adjacent such LEDs or pcLEDs in the array may correspond to a single pixel (picture element) in the display. For example, a group of three individually operable adjacent LEDs or pcLEDs comprising a red emitter, a blue emitter, and a green emitter may correspond to a single color-tunable pixel in the display. Array 610 can be used to project light in graphical or object patterns that can support AR/VR/MR systems

Control input is provided to the sensor system 640, while power and user data input is provided to the system controller 650. In some embodiments modules included in system 600 can be compactly arranged in a single structure, or one or more elements can be separately mounted and connected via wireless or wired communication. For example, array 610, display 620, and sensor system 640 can be mounted on a headset or glasses, with the light emitting array controller and/or system controller 650 separately mounted.

System 600 can incorporate a wide range of optics (not shown) to couple light emitted by array 610 into display 620. Any suitable optics may be used for this purpose.

Sensor system 640 can include, for example, external sensors such as cameras, depth sensors, or audio sensors that monitor the environment, and internal sensors such as accelerometers or two or three axis gyroscopes that monitor an AR/VR/MR headset position. Other sensors can include but are not limited to air pressure, stress sensors, temperature sensors, or any other suitable sensors needed for local or remote environmental monitoring. In some embodiments, control input can include detected touch or taps, gestural input, or control based on headset or display position.

In response to data from sensor system 640, system controller 650 can send images or instructions to the light emitting array controller 630. Changes or modification to the images or instructions can also be made by user data input, or automated data input as needed. User data input can include but is not limited to that provided by audio instructions, haptic feedback, cye or pupil positioning, or connected keyboard, mouse, or game controller.

Devices as described above may include reflective side coatings on the light emitting elements. The reflective side coats optically isolate adjacent light emitting elements, thereby reducing cross-talk and increasing contrast between adjacent light emitting elements.

Devices described above may include different pixels or pcLEDs with differing spectral characteristics, including color. Different pixels or pcLEDs with differing spectral characteristics may appear at different positions in the far-field or otherwise be poorly mixed even when they are directed by the same optical element, such as the projection lens 404. This can be problematic when a uniform beam in the far-field is desired.

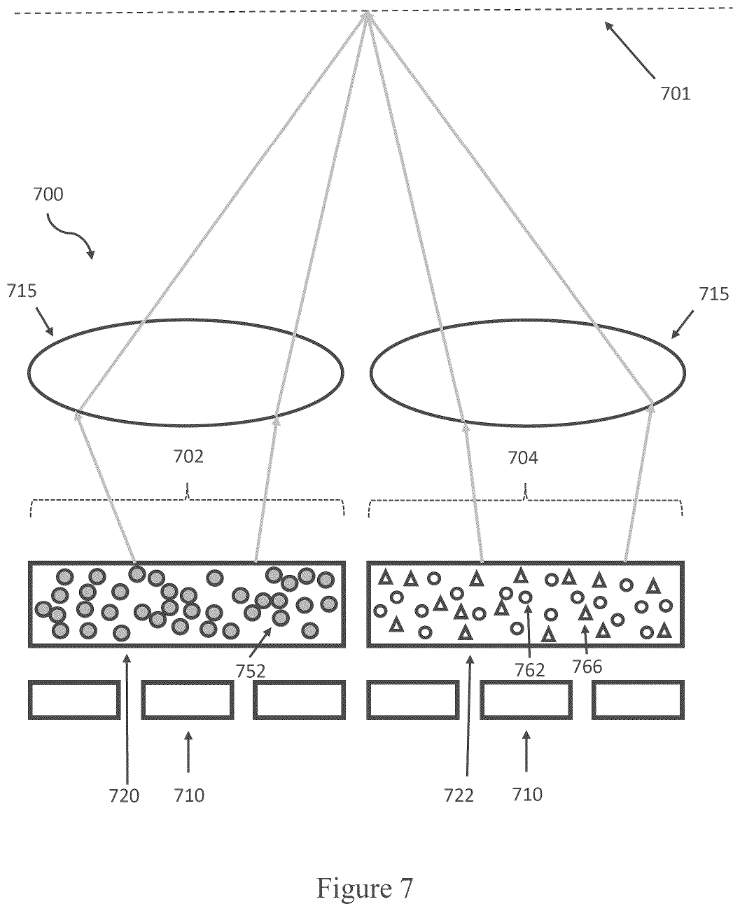

FIG. 7 illustrates embodiments of this invention in the form of a light emitting device 700, having a first array 702 and a second array 704 each with an optical element 715. The light emitting device 700 may be a light engine. The first array 702 includes LEDs 710, a phosphor layer 720, and first phosphor particles 752 in the phosphor layer. The second array 704 includes LEDs 710, an integrated phosphor layer 722, and second phosphor particles 762 and second scattering particles 766 in the integrated phosphor layer. The first array 702 may emit first light of a first color or color temperature and the second array 704 may emit second light of a second color or color temperature different from that of the first light. For example, the first array 702 may emit light of a red, blue, or green color, and the second array 704 may emit light of a red, blue, or green color different from the first array 702. In another example, the first array 702 may emit first light of a cool white while the second array 704 emits second light of a warm white.

The first array 702 and second array 704 may each have an optical element 715. The respective optical elements 715 may be arranged in only the light path of their respective array, or they may just be arranged in the light path of the majority or supermajority of rays emitted from their respective array. The optical elements 715 mix the first light and second light of the first and second array 702 and 704 so that they are uniformly mixed in the far-field, both spatially and spectrally. For example, the far-field may be a surface 701 shown in FIG. 7 (where the light rays depicted coming out of the phosphor layers and through the optical elements converge) such that only one optical element needs to be between the phosphor layer and the far-field for uniform mixing at the surface 701, and the optical elements 715 may be a converging lens. As a result, the first light and second light may be mixed to appear as or substantially as a beam of a single color in the far-field, rather than two spatially and spectrally distinct beams. The respective optical elements 715 may be the same type of lens and the same dimensions as each other, or they may be different type of lens and/or different dimensions as each other.

The first array 702 and second array 704 both include LEDs 710. Each LED 710 may be associated with a single pixel in the array. For example, in FIG. 7 the first array 702 is depicted with three visible pixels and the second array 704 is depicted with three visible pixels. As FIG. 7 depicts a cross section, the arrays could of course be an X by X two-dimensional grid of pixels/LEDs, such as a 3×3, 7×7, or 9×9 array of pixels/LEDs. The LEDs 710 may emit light of a same color as each other, for example blue light, although this is not a requirement and the first array 702 and the second array 704 may respectively include LEDs that emit light of a different color from each other. The first array 702 may have a phosphor layer 720 with first phosphor particles 752 that are different than second phosphor particles 762 disposed in the integrated phosphor layer 722 of the second array 704. For example, the first phosphor particles 752 may absorb light of a first wavelength or first wavelength range and emit light of a second wavelength or wavelength range, while the second phosphor particles 762 may absorb light of a first wavelength or wavelength range and emit light of a third wavelength or wavelength range. For example, the first phosphor particles 752 may absorb blue light emitted from the LEDs 710 and emit green light, while the second phosphor particles may absorb blue light emitted from the LEDs 710 and emit red light. In another example, the second phosphor particles may absorb blue light of a first wavelength emitted from the LEDs 710 and emit blue light of a second wavelength. The first phosphor particles 752 may be or include a different material than the second phosphor particles 762. They may have different shapes, densities, and/or size distributions from each other. Alternatively, they may have the same shape and/or size distributions as each other.

The phosphor layer 720 may have a different density than the first phosphor particles 752 than the density of second phosphor particles 762 of integrated phosphor layer 722. The different density may be greater or lesser. This is because the first array 702 and second array 704 are designed to emit different colors, such that the first phosphor particles 752 and the second phosphor particles 762 may have different distances in color space between the light of the LEDs 710 and their respective output colors. As a result, these different color space distances may necessitate a difference in relative amount of phosphors included in the phosphor layer 720 of the first array 702 versus that included in the integrated phosphor layer 722 of the second array 704. If the phosphor layer 720 and the integrated phosphor layer 722 are of the same form factor, i.e., the same dimensions, one must have a greater density to account for the increase in amount of phosphor particles needed to reach the desired spectral characteristics of the emitted light. Considering hypothetically if the integrated phosphor layer 722 of second array 704 did not include the second scattering particles 766, the increased density of phosphor particles in one of the phosphor layers of the first array 702 or second array 704 may result in greater scattering within that phosphor layer compared to the other.

If the phosphor layer 720 and the integrated phosphor layer 722 do not have different densities of phosphor particles, one of them may have a larger form factor than the other in order to accommodate the difference in amounts of phosphors required. This may also result in increased scattering of one phosphor layer over the other.

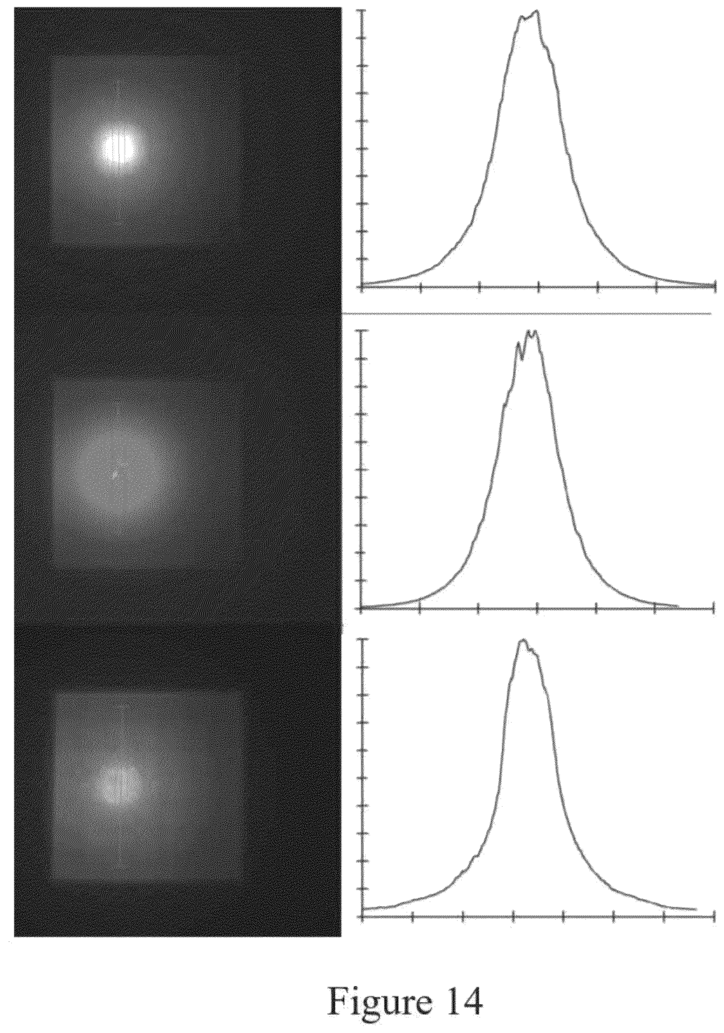

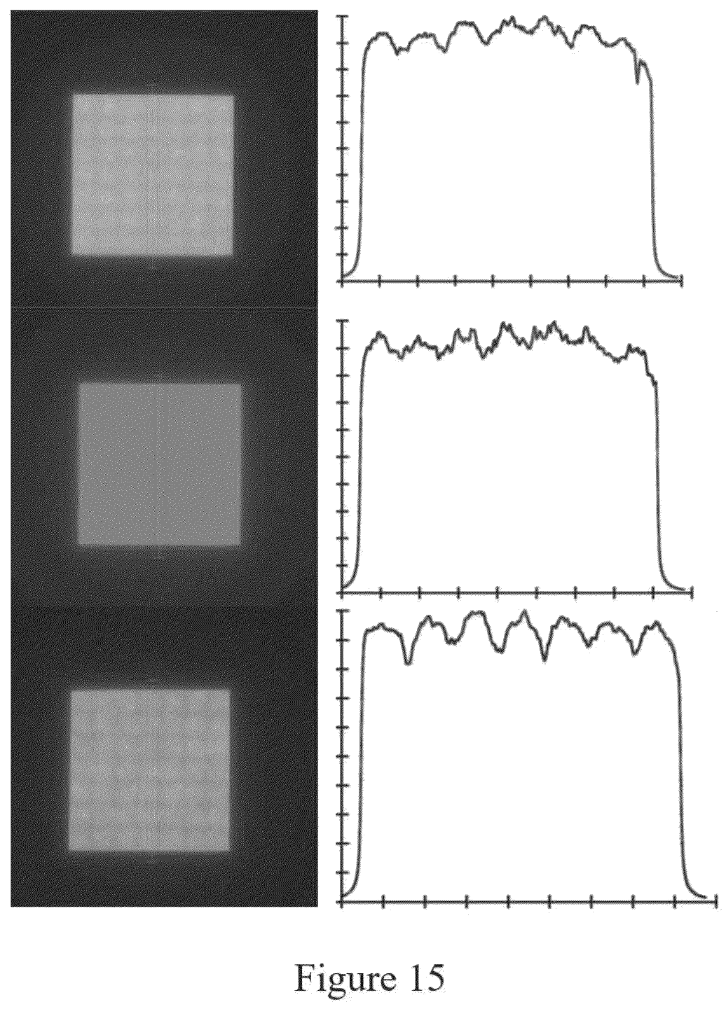

In order to address this discrepancy in scattering between phosphor layers of different arrays, scattering particles may be integrated in the integrated phosphor layer 722. The integrated phosphor layer 722 may have a greater or lesser density of phosphor particles than the phosphor layer 720, such that, without the second scattering particles 766, the light travelling through integrated phosphor layer 722 may be more or less scattered than that travelling through phosphor layer 720. The second scattering particles 766 normalize this difference in scattering between integrated phosphor layer 722 and phosphor layer 720. That is, the second scattering particles 766 included in integrated phosphor layer 722 may increase or decrease scattering in the integrated phosphor layer 722 so that both the phosphor layer 720 and the integrated phosphor layer 722 has a same or substantially the same amount of scattering. In other words, the second scattering particles 766 may broaden or narrow the line profile of the second array 704 to match or more closely match the line profile of the first array 702. As a result, the first light emitted by the first array 702 and the second light emitted by the second array 704 is able to be uniformly mixed by the optical elements 715. Without the second scattering particles 766, the first light and the second light may, even after travelling through the optical elements 715, have color and/or spatial separation in the far-field. FIGS. 14 and 15 show, respectively, the line profile of luminance in the near-field without the scattering particles included. The line profile in the far-field may be similar and/or proportional to that of the near-field. In other words, the relative difference in spatial widths between arrays in the near-field may be preserved in the far-field depending on the optical element through which the light travels through. Alternatively, the optical element may warp the line profiles so that the relative differences of the arrays in the far-field are different than in the near-field. FIG. 14 shows a green pcLED array, a red pcLED array, and a green pcLED array with one pixel in each array turned on. As can be seen, the line profile for each of these pixels is different (taken from a cross-section of the line superimposed over the actual pixel image), as they are spread out at different widths from each other. The widths may be measured at the full-width half maximum or at the base of the line profile, for example, although it may be measured in any other location as well. because the difference in line profiles between pixels results from the scattering from phosphors of different colors and/or compositions being different. FIG. 15 shows the same arrays with all pixels turned on. The line profile for each of these arrays is again different. As a result of these difference, for example, the light emitted from light emitting device 700 may show rings of color without the second scattering particles 766. Or, the light emitted from the light emitting device 700 may require additional complicated and/or bulky optical elements in addition to optical elements 715 to eliminate the rings of color without the second scattering particles 766. When the scattering particles are included in one or more of the phosphor layers, the rings of color may be eliminated from the emitted beam so that only a solid circle of a single color is visible in the far field, without the additional use of more optical elements. In other words, the scattering profiles of light sources of different colors within a light engine may be normalized. Once it has been normalized, the luminance profile in the far-field for a single pixel may be identical or substantially identical between light sources or arrays of different colors. That is, the luminance profiles of different arrays may have the same or substantially the same spatial widths at every point such that the curves of the line profiles overlap perfectly or near perfectly.

The presence, composition, transparency, index of refraction, shape, density and/or other like characteristics of scattering particles in some or all of the phosphor layers of light emitting device 700 are tunable based on the desired luminance profile of the light emitting device 700 and the specific colors emitted from the individual arrays of the light emitting device 700. The type and amount of scattering particles may be chosen based on the specific goals and elements of each light emitting device 700.

The scattering particles may be any particles that are capable of achieving a tunable increase in scattering without significant optical loss. They may be particles with high transparency and high refractive index. For example, they may be particles being entirely of or including alumina, titania, or glass. The scattering particles may alter the trajectory of light that is incident upon them, and may not alter the wavelength of light that is incident upon them. For example, the scattering particles may be non-phosphorescent, although this is not a requirement. The scattering particles may be a different size and/or material than the phosphor particles.

The scattering particles may be tunable for mixing into phosphor layers as well. That is, the scattering particles may be tunable in size for mixing with the phosphor particles in the phosphor layer without size segregation. For example, the second scattering particles 766 may be chosen to have a size distribution that is the same as or substantially the same as that of the second phosphor particles 762 within the integrated phosphor layer 722. Additionally, the scattering particles may undergo surface functionalization. A silane or other functional molecule may be applied to the surface of each scattering particle so that it becomes more energetically favorable in a binder of the phosphor layer within which the scattering particle and the phosphor particles are to be suspended. This surface functionalization improves the mixing of the scattering particle with the phosphor particles. In both the phosphor layer 720 and the integrated phosphor layer 722, the first phosphor particles 752 and second phosphor particles may be uniformly disposed within their respective layer, e.g., be spatially uniform from one pixel to another, and/or be spatially uniform when considered on a length scale longer than a wavelength of light emitted from the LED 710. The second scattering particles 766 may likewise be uniformly disposed within the integrated phosphor layer 722. In addition, deagglomeration and/or two-phase mixing may be employed to aid in the formation of an integrated phosphor layer with scattering particles.

The phosphor layers may include binders within which phosphor particle and/or the scattering particles may be suspended. The binders may be organic or inorganic, and may be transparent. The binders may be index matched with the phosphor particles and/or the scattering particles, or they may have a different index of refraction. As examples, the binder may be silicone, aluminum oxide, and/or other similar materials.

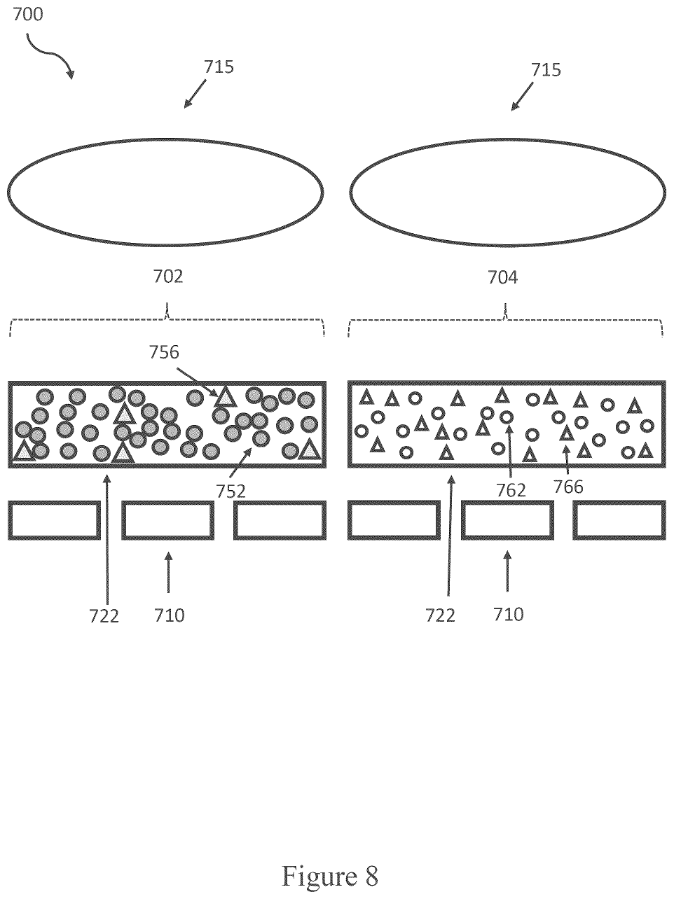

FIG. 8 illustrates embodiments of this invention in the form of light emitting device 700, having a first array 702 having an integrated phosphor layer 722 with first scattering particles 756, and a second array 704 having an integrated phosphor layer 720 with second scattering particles 766. In this case, scattering particles are included in both the first array 702 and second array 704. The first scattering particles 756 may have a different composition, density, size, and/or shape than scattering particles 762. For example, the if first phosphor particles 752 have a different size distribution than second phosphor particles 762, first scattering particles 756 may be chosen to have a different size distribution than second scattering particles, e.g., a size distribution matching or substantially matching that of first phosphor particles 752. The first scattering particles 756 may cause greater or lesser scattering than second scattering particles 766. For example, the first scattering particles 756 may narrow the line profile width of a pixel's luminance from first array 702, while second array 704 may broaden the line profile width of a corresponding pixel's luminance from second array 704, such that the corresponding pixel's luminance from the first and second array 702 have matching line profiles. Alternatively, the first scattering particles 756 may broaden the line profile width of a pixel's luminance from first array 702, while second array 704 may narrow the line profile width of a corresponding pixel's luminance from second array 704, such that the corresponding pixel's luminance from the first and second array 702 have matching line profiles.

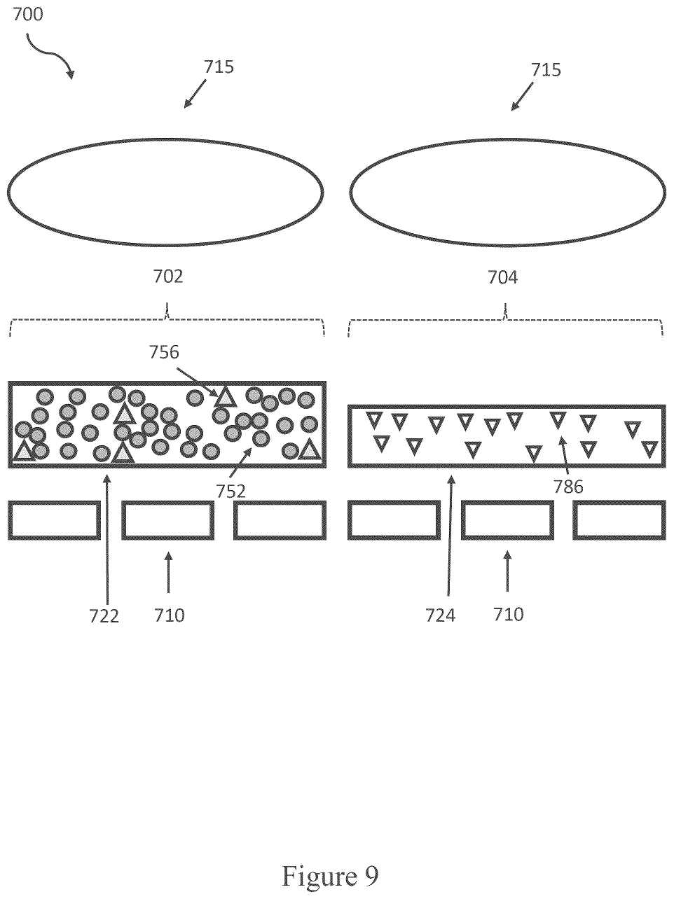

FIG. 9 illustrates embodiments of this invention in the form of light emitting device 700, having a first array 702 having an integrated phosphor layer 722 with first scattering particles 756, and a second array 704 without a phosphor layer but having a scattering layer 724 with third scattering particles 786. The second array 704 may be a direct emitting array designed to emit the light from the LED 710 without phosphor conversion. For example, the second array 704 may be designed to emit blue light from the LED 710. In any case, the line profile of luminance from light emitted by the second array 704 may need to be broadened or narrowed in order to match the light emitted from the first array 702. For example, first scattering particles 756 may broaden the line profile of first array 702 while third scattering particles 786 narrows the line profile of second array 704, or vice versa. Alternatively, both first scattering particles 756 and third scattering particles 786 may narrow the line profiles of their respective arrays, or both may broaden the line profiles of their respective arrays. In this case, the narrowing or broadening effect of the first versus third scattering particles may be different from each other. This setup might be desired if a particular line profile of for the light emitting device 700 is desired outside the range of line profiles bounded by the natural line profiles of first and second arrays 702, 704 without the first and third scattering particles 756, 786. In other words, the scattering particles in scattering layers 724 scatter light and broaden or narrow the line profile of their respective array in the same way as scattering particles within integrated phosphor layers containing the scattering particles.

The scattering layer 724 may include a binder within which the third scattering particles are disposed. The binder may be a same binder as that used in phosphor layer 720. Alternatively, the binder in the scattering layer 724 is a different binder from that used in phosphor layer 720.

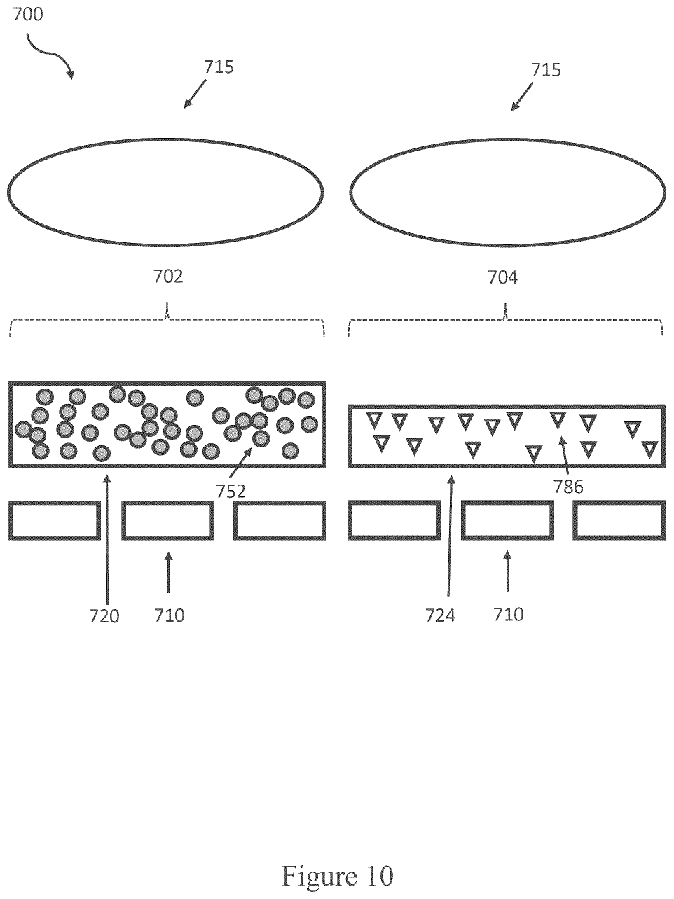

FIG. 10 illustrates embodiments of this invention, with a similar setup to FIG. 9 but with the first array 702 having a phosphor layer 720 with first phosphor particles 752 without any scattering particles. In this case the direct emitting second array 704 has third scattering particles 786 designed to increase or decrease scattering (e.g., broadening or narrowing the line profile of light emitted from the second array 704) to match the line profile of first array 702.

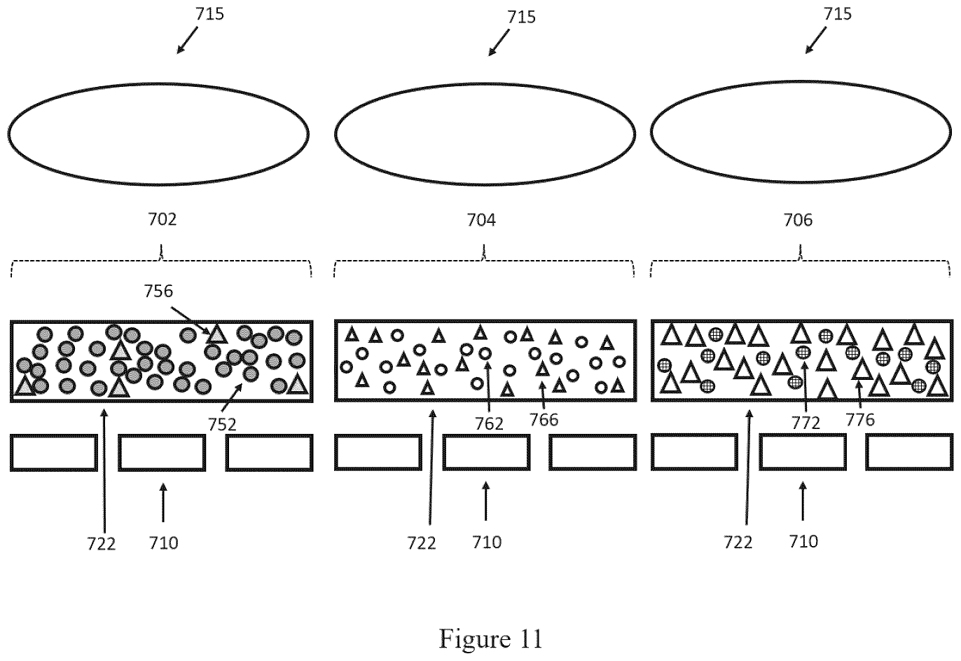

FIG. 11 includes a first array 702 having an integrated phosphor layer 722 with first scattering particles 756, a second array 704 having an integrated phosphor layer 722 with second scattering particles 766, and a third array 706 having an integrated phosphor layer 722 with third scattering particles 776. The third scattering particles 776 may differ from or be the same as the first scattering particles 756 and/or the second scattering particles 766 in the same way as the second scattering particles 766 differ from the first scattering particles 756 as described in the description of FIG. 8 and the other figures above, in terms of shape, size, density, composition, and/or other characteristics.

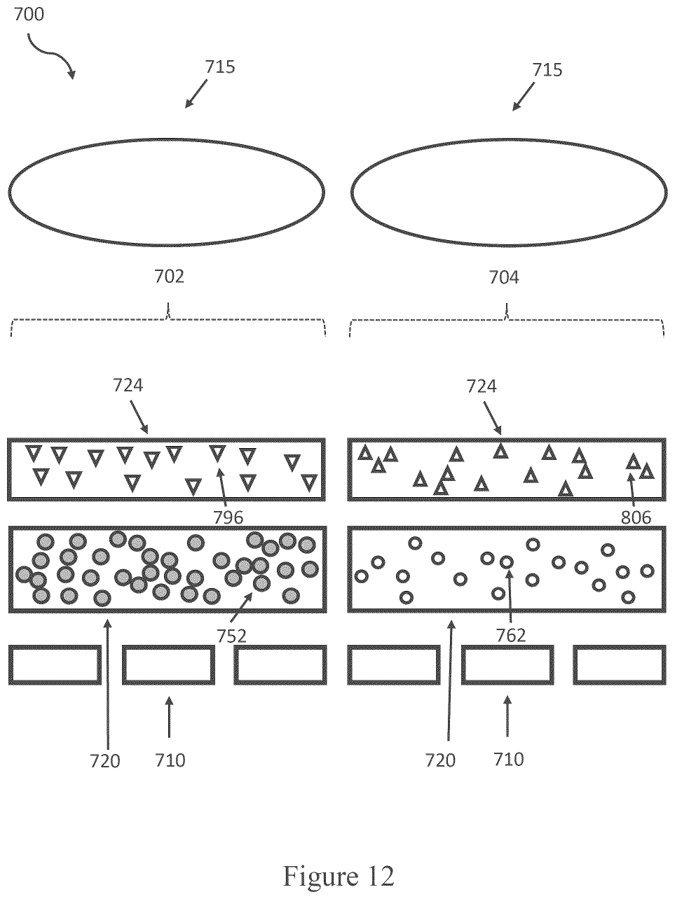

FIG. 12 includes a first array 702 having a phosphor layer 720 without scattering particles and a scattering layer 724 with fourth scattering particles 796, and a second array 704 with a phosphor layer 722 without scattering particles and a scattering layer 724 with fifth scattering particles 796. The fourth scattering particles 796 and the fifth scattering particles 806 may differ from each other in the same way as the second scattering particles 766 differ from the first scattering particles 756 as described in the description of FIG. 8 and the other figures above, in terms of shape, size, density, composition, and/or other characteristics. The scattering layers 724 in FIG. 12 are disposed above the phosphor layers 720 in their respective arrays. They may be in direct contact with the phosphor array or spaced apart. Even when they are in direct contact they may be considered to be in a separate layer, for example with respect to mixing properties. Alternatively, the scattering layers 724 may be below the phosphor layers 720 to be between the phosphor layers 720 and the LEDs 710. Other than these characteristics, the scattering layers 724 in FIG. 12 may be the same as or similar to the scattering layer 724 disposed in the direct emitting array of FIG. 9.

The scattering particles in scattering layers 724 scatter light and broaden or narrow the line profile of their respective array in the same way as scattering particles within integrated phosphor layers containing the scattering particles. Because these scattering particles are placed in separate scattering layers 724, their size does not matter with respect to size segregation with the phosphors they are disposed over, since they are disposed in separate layers. They also do not need to undergo surface functionalization.

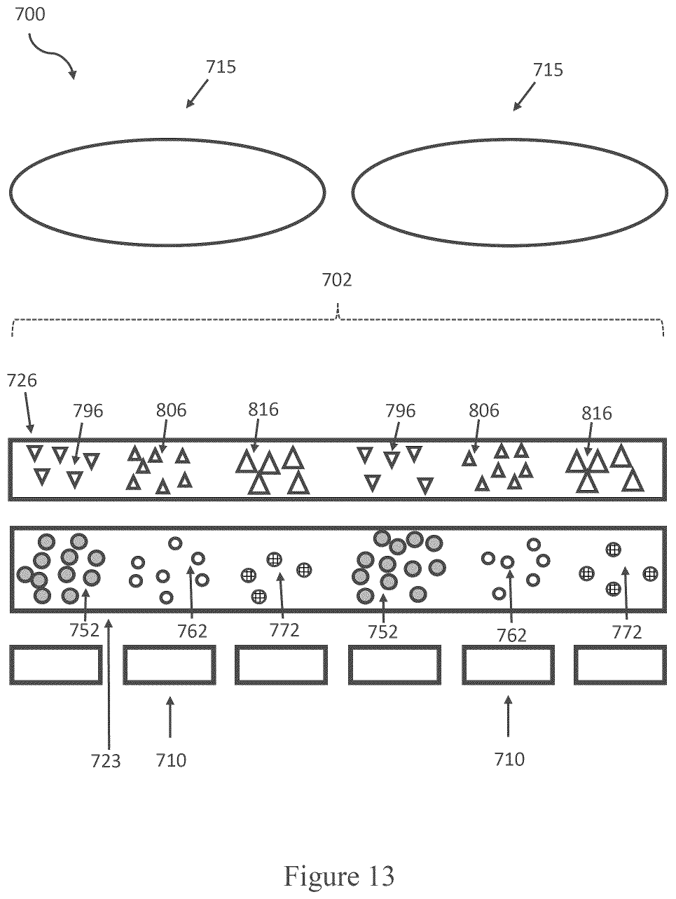

FIG. 13 includes a first array 702 having a spatially varying phosphor layer 723 which spatially varies in phosphor characteristics and a spatially varying scattering layer 726 which spatially varies in scattering particle characteristics. Phosphor and scattering particle characteristics include material, shape, size and/or size distribution, and/or density. For example, characteristics for phosphors and scattering particles disposed over individual pixels emitting the same color (but potentially not adjacent to each other) may be the same for all of them. As a result, even though the spatially varying phosphor layer 723 includes three types of phosphor regions 752, 762, and 772 intended for three different types and/or colors of pixels, the spatially varying scattering layer 726 has three types of regions of scattering particles 796, 806 and 816 which correspond respectively to those three types of pixels. In this way, the three types of regions of scattering particles 796, 806, and 816 provide different levels of scattering to normalize the three types of pixels so that they have, for example, the same or substantially the same line profiles of luminance in the far-field after they travel through the optical elements 715. Respective regions of scattering particles 796, 806, and 816 and respective phosphor regions 752, 762, and 772 may only be disposed within the bounds of imaginary vertical lines drawn from the side walls of their respective LEDs 710, although this is not a requirement.

This disclosure is illustrative and not limiting. Further modifications will be apparent to one skilled in the art in light of this disclosure and are intended to fall within the scope of the appended claims.

1. A light emitting device, comprising:
at least one optical element;
a first light emitting array configured to emit a first light through the at least one optical element into a far-field, the first light comprising light of a first wavelength and light of a second wavelength and having a first luminance line profile in the far-field with a first spatial width, the first light emitting array comprising:
first light emitting diodes (LEDs) configured to emit the light of the first wavelength; and
a first phosphor layer arranged in an optical path of the first LEDS and comprising first phosphor particles configured to absorb at least some of the light of the first wavelength and emit the light of the second wavelength; and
a second light emitting array disposed adjacent to the first light emitting array and configured to emit a second light through the at least one optical element into the far-field, the second light comprising light of the first wavelength and light of a third wavelength, the second light emitting array comprising:
second LEDs configured to emit the light of a third wavelength;
a second phosphor layer arranged in an optical path of the second LEDs comprising:
second phosphor particles configured to absorb at least some of the light of the third wavelength and emit light of the fourth wavelength; and
second scattering particles mixed with the second phosphor particles in the second phosphor layer and arranged to scatter at least one of the light of the third wavelength emitted by the second LEDs and the light of the fourth wavelength emitted by the second phosphor particles so that a second luminance line profile of the second light emitted by the second light emitting array in the far-field is broadened or narrowed to have a second spatial width.

2. The light emitting device of claim 1, wherein the first light is one of red, blue, and green, and the second light is another one of red, blue, and green different from the first light.

3. The light emitting device of claim 1, wherein the light of the first wavelength is blue, the light of the second wavelength is one of yellow, green, and red, and the light of the fourth wavelength is another one of yellow, green, and red different from the light of the second wavelength.

4. The light emitting device of claim 1, wherein the first spatial width is substantially as wide as the second spatial width.

5. The light emitting device of claim 1, wherein the first phosphor layer comprises first scattering particles arranged to scatter at least one of the light of the first wavelength emitted by the first LEDs and the light of the second wavelength emitted by the second phosphor particles so that the first luminance line profile in the far-field is broadened or narrowed to have the first spatial width.

6. The light emitting device of claim 5, wherein the first luminance line profile is broadened or narrowed to have the first spatial width and the second luminance line profile is a same one of broadened or narrowed as the first illuminance profile, to have the second spatial width.

7. The light emitting device of claim 1, wherein the at least one optical element is one or more lenses.

8. The light emitting device of claim 1, wherein the second phosphor particles are uniformly distributed in the second phosphor layer, and the second scattering particles are uniformly distributed in the second phosphor layer.

9. The light emitting device of claim 1, wherein the second scattering particles comprise or are alumina, titania, or glass.

10. The light emitting device of claim 1, wherein the first phosphor layer does not comprise scattering particles of alumina, titania, or glass.

11. The light emitting device of claim 1, wherein the first phosphor layer and the second phosphor layer are discrete layers spaced out from each other to not be in direct contact.

12. The light emitting device of claim 1, wherein the first phosphor layer and the second phosphor layer are integrated to form a continuous phosphor layer.

13. The light emitting device of claim 1, further comprising a third light emitting array disposed adjacent to one of the first and second light emitting array, and configured to emit a third light through the at least one optical element into the far-field comprising light of a fifth wavelength, the third light emitting array comprising third LEDs configured to emit light of the fifth wavelength.

14. The light emitting device of claim 1, wherein the first wavelength and the third wavelength are a same wavelength.

15. A light emitting device, comprising:
at least one optical element;
a first light emitting array configured to emit a first light through the at least one optical element into a far-field, the first light comprising light of a first wavelength and light of a second wavelength and having a first luminance line profile in the far-field with a first spatial width, the first light emitting array comprising:
first light emitting diodes (LEDs) configured to emit the light of the first wavelength; and
a first phosphor layer comprising first phosphor particles configured to absorb at least some of the light of the first wavelength and emit the light of the second wavelength; and
a second light emitting array disposed adjacent to the first light emitting array and configured to emit a second light through the at least one optical element into the far-field, the second light comprising light of a third wavelength, the second light emitting array comprising:
second LEDs configured to emit the light of the third wavelength; and
a second scattering layer comprising second scattering particles arranged to scatter at least one of the light of the third wavelength emitted by the second LEDs so that a second luminance line profile of the second light emitted by the second light emitting array in the far-field is broadened or narrowed to have a second spatial width;
wherein the second light emitting array does not comprise any phosphor material between the second LEDs and the second scattering layer.

16. The light emitting device of claim 15, wherein the first phosphor layer has first scattering particles comprises first scattering particles arranged to scatter at least one of the light of the first wavelength emitted by the first LEDs and the light of the second wavelength emitted by the second phosphor particles so that the first luminance line profile in the far-field is broadened or narrowed to have the first spatial width.

17. The light emitting device of claim 15, further comprising a third light emitting array disposed adjacent to one of the first and second light emitting array, and configured to emit a third light through the at least one optical element into the far-field comprising light of a fourth wavelength and light of a fifth wavelength, the third light emitting array comprising:
third LEDs configured to emit light of the fourth wavelength;
a third phosphor layer arranged in an optical path of the third LEDs comprising:
third phosphor particles configured to absorb at least some of the light of the fourth wavelength and emit light of the fifth wavelength; and
third scattering particles arranged to scatter at least one of the light of the fourth wavelength emitted by the third LEDs and the light of the fifth wavelength emitted by the third phosphor particles so that a third luminance line profile of the third light emitted by the second light emitting array in the far-field is broadened or narrowed to have a third spatial width.

18. A light emitting device, comprising:
at least one optical element;
a first light emitting array configured to emit a first light through the at least one optical element into a far-field, the first light comprising light of a first wavelength and light of a second wavelength and having a first luminance line profile in the far-field with a first spatial width, the first light emitting array comprising:
first light emitting diodes (LEDs) configured to emit the light of the first wavelength;
a first phosphor layer comprising first phosphor particles configured to absorb at least some of the light of the first wavelength and emit the light of the second wavelength; and
a first scattering layer, comprising first scattering particles arranged to scatter at least one of the light of the first wavelength emitted by the first LEDs and the light of the second wavelength emitted by the first phosphor particles so that a first luminance line profile of the first light emitted by the first light emitting array in the far-field is broadened or narrowed to have the first spatial width; and
a second light emitting array disposed configured to emit a second light through the at least one optical element into the far-field, the second light comprising light of a third wavelength and light of a fourth wavelength, the second light emitting array comprising:
second LEDs configured to emit the light of the third wavelength;
a second phosphor layer comprising second phosphor particles configured to absorb at least some of the light of the third wavelength and emit light of the fourth wavelength; and
a second scattering layer, comprising second scattering particles arranged to scatter at least one of the light of the third wavelength emitted by the second LEDs and the light of the fourth wavelength emitted by the second phosphor particles so that a second luminance line profile of the second light emitted by the second light emitting array in the far-field is broadened or narrowed to have a second spatial width;
wherein the second scattering particles differ from the first scattering particles in at least one of shape, density, and size distribution.

19. The light emitting device of claim 18, further comprising a third light emitting array disposed adjacent to one of the first and second light emitting array, and configured to emit a third light through the at least one optical element into the far-field comprising light of a fifth wavelength, the third light emitting array comprising:
third LEDs configured to emit light of the fifth wavelength;
a third scattering layer comprising third scattering particles arranged to scatter the light of the fifth wavelength emitted by the third LEDs so that a third luminance line profile of the second light emitted by the third light emitting array in the far-field is broadened or narrowed to have a third spatial width.

20. The light emitting device of claim 19, wherein:
the third light emitting array further comprises a third phosphor layer comprising third phosphor particles configured to absorb at least some of the light of the fifth wavelength and emit light of the sixth wavelength,
the third light emitted by the third light emitting array through the at least one optical element into the far-field further comprises light of the sixth wavelength, and
the third scattering layer is arranged to scatter light of the sixth wavelength emitted by the third phosphor layer.
